(19) United States
(12) Patent Application Publication
(10) Pub. No.: US 2025/0172771 A1
(43) Pub. Date: May 29, 2025

(54) SCALABLE PHOTONIC SRAM-BASED IN-MEMORY COMPUTING AND TENSOR CORE

(71) Applicant: University of Southern California, Los Angeles, CA (US)

(72) Inventors: Ajey P. Jacob, Watervliet, NY (US); Akhilesh Jaiswal, Madison, WI (US); Sugeet Sunder, Los Angeles, CA (US)

(21) Appl. No.: 18/964,271

(22) Filed: Nov. 29, 2024

Related U.S. Application Data
(60) Provisional application No. 63/604,149, filed on Nov. 29, 2023.
(60) Provisional application No. 63/549,289, filed on Feb. 2, 2024.

(51) Int. Cl. G02B 6/42; G02B 6/293

(52) U.S. Cl. CPC G02B 6/4215; G02B 6/29343

(57) ABSTRACT

Provided is memory circuit comprising a plurality of ring resonators optically coupled to one or more waveguides and electrically coupled to one or more diodes, where the diodes are optically coupled to the one or more waveguides, which is configured to provide optical SRAM or another type of memory with in-memory computing. Further provided is an array of said memory circuits.

### CROSS-REFERENCE TO RELATED APPLICATIONS

This application claims the benefit of U.S. Provisional Pat. App. 63/604,149, titled SCALABLE PHOTONIC SRAM-BASED IN-MEMORY COMPUTING TENSOR CORE, filed 29 Nov. 2023, and U.S. Provisional Pat. App. 63/549,289, titled SCALABLE PHOTONIC SRAM-BASED IN-MEMORY COMPUTING TENSOR CORE, filed 2 Feb. 2024, the entire content of each of which is hereby incorporated by reference.

### BACKGROUND

As data collection, data processing, computing, etc. based on large amounts of data (for example, machine learning inference, foundational models, generative artificial intelligence (AI) etc.) become more common, high-speed data-intensive computing becomes desirable, which may include demands for computing in which data storage and processing (e.g., pre-processing, summation, multiplication, convolution, etc.) occur in the same circuit, which may eliminate bottleneck(s) between data storage and processing. Integration of processing, including partial processing, mathematical operations, etc., into data collection or storage circuits may extend processor capabilities and increase data processing speeds.

While the present techniques are susceptible to various modifications and alternative forms, specific embodiments thereof are shown by way of example in the drawings included or described herein. The drawings may not be to-scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims. Further, the description of problems (to be solved, with other techniques, technical problems, etc.) should not be read to imply that all embodiments must fully eliminate those problems, or that any techniques suffering to some degree from such problems are disclaimed, as various inventive techniques are described and various engineering and cost trade-offs may result in only subsets of such problems being mitigated only partially by some embodiments consistent with the present techniques.

### SUMMARY

The following is a non-exhaustive list of some aspects of the present techniques. These and other aspects are described in the following disclosure.

Some aspects include a memory cell, which may be a static random-access memory (SRAM) cell.

Some aspects include an optical memory cell.

Some aspects include an electro-optical memory cell.

Some aspects include one or more optical filters, which may be one or more resonator, in a memory cell. In some embodiments, the one or more optical filters may be switches.

Some aspects include one or more waveguides, including waveguides optically coupled to one or more optical resonators in one or more embodiments. In some embodiments, the one or more optical resonators may be ring resonators. In some embodiments, the one or more optical resonators may be micro ring resonators. In some embodiments, waveguides may be optically coupled with one or more optical source, including a diode, photodiode, laser, etc. as an optical source. In some embodiments, the optical source may be a narrow wavelength (e.g., having a narrow wavelength range on the order of 1 nm, 10 nm, etc.) optical source. In some embodiments, the optical source may be a broadband optical source, such as having a wavelength range much greater than a through wavelength range of one or more optical resonators. In some embodiments, the optical source may be a multi-wavelength optical source, which may have multiple (including distinct) wavelength ranges. In some embodiments, a memory cell may have multiple optical sources. In some embodiments, an optical source may supply an optical signal to multiple optical filters or other optical circuit elements.

Some aspects include electrical interconnects, in a memory cell. The electrical interconnects may include filter modulators, such as electro-optical modulators for one or more ring resonators. Some aspects include electrical connections to one or more optical sources, such as a photo diode, which may supply electrical signals for controlling output of the one or more optical sources. Some aspects include electrical circuitry, which may be electro-optical circuitry, such as diodes, transistors, amplifiers, etc., to modify input and output of optical elements of a memory cell.

Some aspects include a memory cell with a word line, which may be an optical word line.

Some aspects include a memory cell with a bit line, which may be an optical bit line.

Some aspects include a memory cell where a bit value is stored electronically, such as as a voltage, a charge, a current, etc. Some aspects include a memory cell where a bit value is read optically, such as as a frequency, wavelength, frequency shift, wavelength shift, etc. Some aspects include a memory cell where a bit value is written, erased, changed, etc. by application of electrical biasing (e.g., voltage biasing, reverse biasing, etc.). Some aspects include a memory cell where a bit value is written, erased, changed, etc. by application of optical input, such as to one or more electro-optical transducer, which may generate electrical storage of the bit value, such as as a voltage, charge, current, etc. In some embodiments, six optical resonators may comprise the read circuity of the memory cell, where the optical resonators may function analogously (or non-analogously) to six transistors in a 6T SRAM cell, such as for reading of the SRAM cell. In some embodiments, the electronic circuity of the memory cell may be provided with external biasing. In some embodiments, external electrical biasing may write or erase a bit value. In some embodiments, external electrical biasing may adjust a turn on or turn off value of the memory cell, which may be electronic or optical. In some embodiments, the optical circuits of the memory cell may be supplied with electronic biasing, optical signal (such as from a waveguide), etc.

Some aspects include a compute ring (or other electro-optical filter, such as an optical resonator, micro ring switch, etc.), which may select input to or output from the memory cell.

Some aspects include a memory cell configured to perform multiplication, such as of an input value represented by an input wavelength (for example, a wavelength λ) by a stored value (for example, a value Q stored on electronic components of the memory cell). In some embodiments, the output of the memory cell may be an intensity value, such as a light intensity value. In some embodiments, the output value may be the input light intensity value multiplied by the stored value (e.g., value Q). In some embodiments, the output of the memory cell may be at the same wavelength as the optical input. In some embodiments, output of the memory cell may be wavelength shifted from the wavelength of the optical input.

Some aspects include a memory cell configured to perform multiple multiplications operations, such as simultaneously, sequentially, etc. In some embodiments, the multiple multiplications may be input simultaneously, sequentially, etc. and output in the same or different manner (e.g., sequentially, simultaneously, etc.). In some embodiments, output of the multiple multiplication operations may be multiplexed.

Some aspects include multiple compute rings, which may operate to increase throughput of a multiple multiplication operation (or another parallel operation), such as if each compute ring selects for one or more of the multiple multiplication operations.

Some aspects include compute rings on a bitline and bitline bar, which may operate to increase throughput of a multiple multiplication operation (or another parallel operation), such as if each bitline and bitline bar compute ring selects for one or more of the multiple multiplication operations.

Some aspects include a memory cell configured to perform a convolution operation. Some aspects include a memory cell configured to perform a summation (e.g., addition) operation. Some aspects include a memory cell configured to perform one or more summation and one or more multiplication operations. Some aspects include multiple word lines. Some aspects include multiple bit lines.

Some aspects include a memory cell (or array of memory cells) configured to perform a transpose operation. Some aspects include a memory cell (or array of memory cells) configured to perform one or more transpose operation and one or more convolution operation.

Some aspects include one or more electro-optic ADCs. Some aspects include one or more electro-optic DACs.

Some aspects include a memory cell (or array of memory cells) configured to perform an accumulation. Some aspects include a memory cell (or array of memory cells) configured to perform a multiply-accumulate (MAC). Some aspects include a memory cell (or array of memory cells) configured to perform a multiple-add (MAD). Some aspects include a memory cell with an intermediate output, in addition to an output.

Some aspects include a memory cell containing an array of any other embodiment. Some aspects include an array of the memory cells of any other embodiment.

In some embodiments, output of an in-memory computation may be transmitted optically, such as by a waveguide. In some embodiments, output of the in-memory computation may be transmitted by

Some aspects include a power splitter, such as an optical power splitter to split output of an optical source, such as to multiple waveguides.

Some aspects include absorbers, such as light absorbers (e.g., A3, A4, A5, and A6), which may absorb light coupled through multiple resonators and not to an output waveguide. Some aspects include a memory cell which is volatile memory.

Some aspects include a memory cell which is nonvolatile memory, such as nonvolatile SRAM (nvSRAM).

Some aspects include additional processing circuitry in the memory cell or array of memory ce;; s.

Some aspects include a method of fabricating one or more memory cell or an array thereof.

Some aspects include a memory cell fabricated in Si, SiN, III-V materials, Lithium niobate, ferroelectric materials, organic materials, graphene, two-dimensional materials, or a combination thereon. Some aspects include a memory cell in which photonic elements are fabricated of the previously listed materials.

Some aspects include a memory cell fabricated in SiGe, Ge, InP, GaN, graphene, two-dimensional materials, or a combination thereof. Some aspects include a memory cell in which electronic elements are fabricated of the previously listed materials.

Some aspects include wafer scale integration of one or more memory cell.

Some aspects include clock speed of a memory cell which is greater than 20-100 GHz.

Some aspects include a method of performing a multiplication operation using bit values of a memory cell or array thereof.

Some aspects include a method of performing an addition operation using bit values of a memory cell or array thereof.

Some aspects include a method of performing an accumulation operation using bit values of a memory cell or array thereof.

Some aspects include a method of performing a convolution operation using bit values of a memory cell or array thereof.

Some aspects include a method of performing a transpose operation using bit values of a memory cell or array thereof.

Some aspects include a method of performing one or more of any previously described methods.

Some aspects include a method of performing multiple different of any previously described methods.

Some aspects include a method of performing massively parallel operations, such as those operations previously described.

Some aspects include a method of performing erasing of bit values of a memory cell or array thereof.

Some aspects include a method of performing resetting of bit values of a memory cell or array thereof.

Some aspects include a tangible, non-transitory, machine-readable medium storing instructions that when executed by a data processing apparatus cause the data processing apparatus to perform one or more operations including the above-mentioned aspects.

Some aspects include a system, including: one or more processors; and memory storing instructions that when executed by the processors cause the processors to effectuate one or more operations of the above-mentioned aspects.

### BRIEF DESCRIPTION OF THE DRAWINGS

The above-mentioned aspects and other aspects of the present techniques will be better understood when the present application is read in view of the following figures in which like numbers indicate similar or identical elements:

FIG. 1 is a schematic diagram that illustrates an example processing in memory circuit for single bit multiplication, in accordance with one or more embodiments;

FIG. 2 is a schematic diagram that illustrates an example processing in memory circuit for single bit multiplication for multiple wavelengths, in accordance with one or more embodiments;

FIG. 3 is a schematic diagram that illustrates an example processing in memory circuit for single bit multiplication for multiple wavelengths with multiple compute elements, in accordance with one or more embodiments;

FIG. 4 is a schematic diagram that illustrates an example processing in memory circuit for single bit multiplication for multiple wavelengths with multiple compute elements on both bit line and inverse bit line, in accordance with one or more embodiments;

FIG. 5A is a schematic diagram that illustrates an example processing in memory circuit for multi-wavelength, multi-bit convolution, in accordance with one or more embodiments;

FIG. 5B is a schematic diagram that illustrates a representative computing schematic, in accordance with one or more embodiments;

FIG. 6A is a schematic diagram that illustrates an example processing in memory circuit for multi-wavelength, multi-bit convolution and transposition, in accordance with one or more embodiments;

FIG. 6B is a schematic diagram that illustrates an example processing in memory circuit for a combined convolution and transposition operation, in accordance with one or more embodiments;

FIG. 7 is a schematic diagram that illustrates a representative computing schematic for a word-interleaved multi-matrix MAC operation, in accordance with one or more embodiments;

FIG. 8 is a system diagram that illustrates an example computing system comprising processing in pixel, in accordance with one or more embodiments.

While the present techniques are susceptible to various modifications and alternative forms, specific embodiments thereof are shown by way of example in the drawings and will herein be described in detail. The drawings may not be to scale. It should be understood, however, that the drawings and detailed description thereto are not intended to limit the present techniques to the particular form disclosed, but to the contrary, the intention is to cover all modifications, equivalents, and alternatives falling within the spirit and scope of the present techniques as defined by the appended claims.

### DETAILED DESCRIPTION

To mitigate the problems described herein, the inventors had to both invent solutions and, in some cases just as importantly, recognize problems overlooked (or not yet foreseen) by others in the fields of in-memory memory computing. Indeed, the inventors wish to emphasize the difficulty of recognizing those problems that are nascent and will become much more apparent in the future should trends in industry continue as the inventors expect. Further, because multiple problems are addressed, it should be understood that some embodiments are problem-specific, and not all embodiments address every problem with traditional systems described herein or provide every benefit described herein. That said, improvements that solve various permutations of these problems are described below.

For example, this disclosure refers to specific types of computational circuits (e.g., memory, such as static random access memory (SRAM), dynamic random access memory (DRAM), read only memory (ROM), nonvolatile memory etc., electrical circuit elements including transistors, such as nFETs, pFETS, etc., diodes, amplifiers, electrical array elements, such as selectors, bit lines, word lines, sense amplifiers, analog to digital converters (ADCs), digital to analog converters (DACs), etc., optical circuity including resonators, waveguides, waveguide-crossings, optical array elements, such as selectors, bit lines, word lines, etc., electro-optical circuity, including transducers, photodiodes, photodetectors, etc. for visible and other wavelength ranges (e.g., infrared (IR), near IR (NIF), microwave, ultraviolet (UV), etc.), and specific types of processing operations (e.g., multiplication, convolution, transposition, matrix-vector transpose, multiple-accumulate (MAC), multiply-add (MAD), etc.) in illustrative examples. Aspects of this disclosure can instead be practiced with other or additional types of circuits (e.g., other types of memory) and processing operations. Further, well-known structures, components, instruction instances, protocols, and techniques may not have been shown in detail to not obfuscate the description.

In some embodiments, architectures are disclosed with may allow for an optical SRAM with embedded compute elements (e.g., compute rings) to provide computation in-memory. In some embodiments, optical computation may provide high-speed computing on large amounts of data. In some embodiments, parallel computations may be performed in-memory. That said, embodiments are not limited to systems affording all of these benefits, which is not to suggest that any other description is limiting.

Herein, both terms “compute” and “process”—and their grammatical conjugates—are used. Use of “compute” may indicate that one or more calculation (e.g., a mathematical calculation) is performed, but does not require that such calculation is or is not part of a process. Use of “process,” “processor,” or the like may indicate that a determination is being made, a set of steps are being followed, or the like, which may involve one or more calculation, but does not require that an end output is reached in any given step. A computation may be performed by a processor, or a process performed by a compute element, and so on. A compute element may be part of a processor or perform a process. A compute element may be any appropriate compute element, including an electronic compute element, an optical compute element, etc.

Optical signal transmission, such as used in the telecommunication industry, presents unique opportunities for signal multiplexing. That is, multiple optical signals may be transmitted over the same waveguide (or other optical transmission element) encoded in different and therefore non-interfering wavelengths of electromagnetic radiation. While optical signals may have the most robust transmission infrastructure (e.g., multiplexer, amplifiers, demultiplexers, detectors, waveguides, optical fibers, etc.), electromagnetic signals in near-optical wavelength ranges may have the same characteristics. Hereinafter, “optical” may be taken to include, where appropriate, infrared (IR), near IR (NIF), microwave, ultraviolet (UV), etc. wavelengths in some embodiments.

In some embodiments, a set of electro-optical elements, which may be resonators, such as micro-ring resonators, may operate to store (e.g., in memory) information in the form of bits. In some embodiments, the bits may be stored as electrical charge, such as on one or more contacts in electrical communication with one or more resonators. In some embodiments, signals may be converted from electronic to optical and vice versa, such as through the application of charge to contacts associated with optical elements or by the altering of charge by application of one or more optical signals. In some embodiments, a set of electro-optical elements may make up a memory element (e.g., “cell”). The memory element may be any appropriate memory type, such as static random access memory (SRAM), dynamic random access memory (DRAM), read only memory (ROM), nonvolatile memory, etc. The memory element may store a bit, or other data unit—including multiple data units—as electrical charge, an optical signal, etc.

In some embodiments, the memory element may be read, such as by application of an optical or electrical signal which may interact with the stored bit. In some embodiments, the memory element may be read during a compute operation, such as one in which an applied optical or electrical signal may be multiplied, divided, added, etc. by the stored bit. In some embodiments, the memory element may be read, including during a compute operation, by multiple input optical signals. In some embodiments, the memory element may be read by an applied optical or electrical signal, where the output of the memory element may be in the same or a different wavelength, frequency, etc. that the input signal. In some embodiments, the memory element may be written by application of an electrical or optical signal. In some embodiments, the memory element may be erased by application of an input electrical or optical signal. In some embodiments, the bit value may be stored in the memory element by application of a continuous (or semicontinuous, intermittent, etc.) optical or electrical signal. In some embodiments, the stored bit value may be erased by cessation of the application of the optical or electrical signal which stores the bit value. In some embodiments, the stored bit value may survive the cessation of the application of the optical or electrical signal which stores the bit value, and may be erased by an erase signal (e.g., an optical or electrical erasure signal), such an opposite signal, a reset signal, etc.

In some embodiments, an array of memory elements may constructed. The array of memory elements may include multiple memory elements which may be read, written, erased, etc., including concurrently, such as by application of different (for example, multiplexed) optical or electrical signals. The array of memory elements may be accessed by bit lines, word lines, or any other appropriate read, write, erase, etc. lines. The array of memory elements may be monolithically integrated. The array of memory elements may be heterogeneously integrated, including with one or more sensor array, memory elements, etc. In some embodiments, electrical connections may operate on different levels (including on parallel planes) to one or more optical elements. In some embodiments, electrical and optical connections, such as contacts, waveguides, etc., may be in contact or separated (such as by one or more absorber, insulator, passivation, etc. layer) from one another.

In some embodiments, any memory circuit described herein may be electron-optical memory with circuit elements as described in International Publication Number WO 2022/192784 A1, which is hereby incorporated by reference in its entirety.

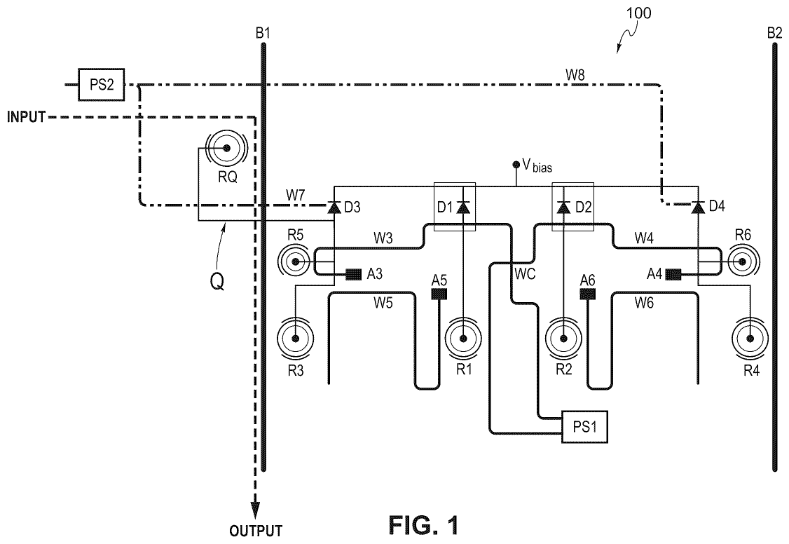

FIG. 1 is a schematic diagram that illustrates an example processing in memory circuit 100 for single bit multiplication, in accordance with one or more embodiments. The memory circuit 100 may be configured for read, write, erase, etc. operations. In some embodiments, the memory circuit 100 may be configured for single bit (e.g., 1 bit) multiplication. If the value of the stored bit is zero, single bit operation may be the same as non-multiplicative read, write, erase, etc. operations. Likewise, if the value of the stored bit is one (1), single bit operation may be the same may be the same as non-multiplicative read, write, erase, etc.

The memory circuit 100 may consist of a set of resonators. The resonators may be ring resonators, microring resonators, cavity resonators, linear resonators, Fabry-Perot cavities, photonic crystal resonators, etc. The resonators may be any appropriate optical resonators. The resonators may couple one or more waveguides. The resonators may be electro-optical resonators, in which one or more electrical contact, such as a top contact, a bottom contact, exterior contact, interior contact, etc., may apply an electrical charge or field which may alter optical properties of the resonator. Likewise, in some embodiments, the optical electromagnetic radiation traveling through the resonator may alter electrical properties (e.g., charge stored, signals transmitted by, etc.) of any appropriate electrical contacts to the resonator. The resonators may have any appropriate electro-optical coupling factor, including a coupling factor which varies by wavelength. Electrical input to the resonators may be direct current (DC), alternating current (AC), charge, etc. The resonators may have any appropriate size and geometry, including the same or different sizes and geometries from one another. As depicted in FIG. 1, the memory circuit may have resonators R1, R2, R3, R4, R5, and R6. In some embodiments, some resonators may be combined, such as by the use of double ring resonators. In some embodiments, additional resonators may be used. As depicted in FIG. 1, the memory circuit may have resonator RQ, which will be described in more detail following.

The memory circuit 100 may consist of a set of waveguides. The waveguides may optically couple one or more of the resonators. The waveguides may be any appropriate waveguides, such as a rectangular (e.g., with a rectangular cross-section) waveguide, a circular waveguide, a recessed waveguide, a dual ridge waveguide, a rib waveguide, a recessed waveguide, a coaxial waveguide, etc. The waveguides may be made of any appropriate material, such as silicon dioxide, GaAs, optical fiber, polymer, etc. The waveguides may be homogeneous or inhomogeneous. The waveguides may any appropriate cross-section, including constant cross-sections, periodic changes in cross-sections (such as may enable transmission via Block modes), etc. The waveguides may have any appropriate mode, such as single mode, multi-mode, etc. As depicted in FIG. 1, the memory circuit 100 may have waveguides W3, W4, W5, and W6. The waveguide W3 may be optically coupled to the resonators R2 and R5. The waveguide W4 may be optically coupled to the resonators R1 and R6. The waveguide R5 may be optically coupled to the resonators R1 and R3. The waveguide R6 may be optically coupled to the resonators R2 and R4. The waveguides W3 and W4 may intersect and waveguide crossing WC. In some embodiments, at the waveguide crossing, the optical signals along the respective waveguides may be non-interfering. In some embodiments, the optical signals may contain some wavelengths or modes (e.g., transverse electric (TE), transverse magnetic (EM), etc.) which interfere (e.g., constructively, destructively) at the waveguide crossing WC, but other wavelengths or modes which are non-interfering. In some embodiments, more or fewer waveguides may be used. As depicted in FIG. 1, the memory circuit 100 may have waveguides W7 and W8. The waveguides W7 and W8 may not be optically connected to any of the resonators, and will be described in more detail following.

The memory circuit 100 may contain one or more absorbers. The absorbers may be optical absorbers or any other appropriate non-reflective waveguide termination. In some embodiments, the absorbers may be saturable absorbers. The absorbers may be any appropriate material, such as textured absorbers, optical fiber terminations, metamaterial absorbers, multi-layer absorbers, etc., which substantially significantly reduce or eliminate return transmission of optical signals along waveguides (e.g., from a waveguide terminus). As depicted in FIG. 1, the memory circuit 100 may have absorbers A3, A4, A5, and A6. The absorber A3 may be at a terminus of the waveguide W3. The absorber A4 may be at a terminus of the waveguide W4. The absorber A5 may be at a terminus of the waveguide W5. The absorber A6 may be at a terminus of the waveguide A6. In some embodiments, additional or fewer absorbers may be present. For example, an additional absorber may be present on the terminus of the waveguide W5 opposite the absorber A5 or an additional absorber may be present on the terminus of the waveguide W6 opposite the absorber A6.

The memory circuit 100 may contain one or more photosource. The photosources may be any appropriate optical source, such as photodiodes, LEDs, single wavelength photosources (e.g, lasers), multi-wavelength photosources, broad spectrum photosources, etc. The photosources may be integrated into the memory cell. The photosources may be controlled by electronic circuitry, such as a driver, signal generator, wavelength selector, etc. (not depicted). The photosources may output optical signals along any appropriate waveguide or to any appropriate element for delivery to any appropriate waveguide. As depicted in FIG. 1, the memory circuit 100 may have photosource PS1 and photosource PS2. The photosource PS1 may be connected, such as by waveguides W3 and W4, to the resonators of the memory cell. The photosource PS2 may be connected to waveguides W7 and W8.

The memory circuit 100 may contain one or more diodes. The diodes may be photodiodes. The diodes may be optically connected to any appropriate waveguide by any appropriate means. For example, the diodes may be photodiodes which receive optical signals from one or more waveguides. The optical connection between the diode and the waveguide may be any appropriate optical connection. The diodes may be integrated into the waveguides. The diodes may function as waveguide termini, such as by absorbing optical signals transmitted along the waveguides. The diodes may function as optical filters, such as by absorbing some of the optical signals transmitted along the waveguides to which they are optically connected. The diodes may pass through optical signals of the waveguides to which they are optically connected. The diodes may have one or more electrical connections. The electrical connections may be any appropriate electrical connections (such as cathode, anode, etc.). The electrical connections may be formed of any appropriate material, such as doped semiconductor, metal layers, etc. As depicted in FIG. 1, the memory circuit 100 may have diodes D1, D2, D3, and D4. The diode D1 may be optically connected to the waveguide W3 and electrically connected to the resonator R1. The diode D2 may be optically connected to the waveguide W4 and electrically connected to the resonator R2. The diode D3 may be optically connected to the waveguide W7 and electrically connected to the resonators R3 and R5. The diode D4 may be optically connected to the waveguide W8 and electrically connected to the resonators R4 and R6.

The memory circuit 100 may have one or more electrical bias connection. In some embodiments, a voltage bias (e.g., Vbias) may be applied to one or more diode, one or more resonator, etc. The voltage bias may include embodiments in which the voltage bias is a grounding. The voltage bias may be applied to multiple elements of the memory circuit 100, including at different voltages to different elements. The voltage bias may be a floating ground. In some embodiments, the voltage bias may be used to reset (e.g., erase) a bit stored in the memory circuit 100. In some embodiments, the voltage bias may be used to bias one or more electrical element (such as a diode, a junction, a field-effect transistor (FET), etc) towards a regime of operation-e.g., a forward bias, a reverse bias, saturation, etc. In some embodiments, the voltage bias may be used to increase or decrease leakage current. As depicted in FIG. 1, the memory circuit 100 may have a voltage bias Vbias which is electrically connected to the diodes D1, D2, D3, and D4. The voltage bias Vbias may be connected in any appropriate manner, including to the diodes D1, D2, D3, and D4 in series (as depicted).

The memory circuit 100 may have one or more bit lines. In some embodiments, the memory circuit 100 may instead or additionally have one or more word lines, which will be described in more detail later. The bit lines of the memory circuit 100 may include a bit line, a bit bar line, etc. The bit line may be any appropriate line, including an optical line such as a waveguide or an electrical line, which may access a bit stored in the memory circuit 100. In some embodiments, the bit line(s) may be optical waveguides and may have any appropriate properties for waveguides of the circuit as previously described. As depicted in FIG. 1, the memory circuit 100 may have bit line B1 and bit bar line B2. The bit line B1 may be optically connected to the resonator RQ. RQ may be one or more resonator which couples a bit stored in the memory circuit 100 (e.g., a bit Q, which may be stored as charge, frequency, intensity, etc.) to the bit line B1. In some embodiments, the bit line B1 may be optically coupled to the resonators R3 and R5. In some embodiments, the bit line B1 may not be optically coupled to the resonators R3 and R5. In some embodiments, the bit bar line B2 may be optically coupled to the resonators R4 and R6. In some embodiments, the bit bar line B2 may not be optically coupled to the resonators R4 and R6. The bit bar line B2 may or may not be optically coupled to (including by being of opposite charge, opposite optical signal direction, etc.) to the bit line B1.

The memory circuit 100 may store a bit, including as trapped charge. The stored bit may be stored in any appropriate manner, including my charge injection through a diode, such as in response to an optical signal applied to a photodiode. The stored bit may be stored in any appropriate location in the memory circuit 100. The stored bit may have any appropriate lifetime. The stored bit may have any appropriate quantity of charge. As depicted in FIG. 1, the memory circuit 100 may have a stored bit Q. The stored bit Q may be stored on an electrical node between the diode D3 and the resonator RQ. The value of the stored bit Q may be read by accessing the stored bit Q through the resonator RQ, which may filter an optical signal of the bit line B1 in response to the value of the stored bit Q.

In some embodiments, an input supplied to the memory circuit 100, such as by the photosource PS2, may be configured to determine the value of the stored bit Q. In some embodiments, the input supplied to the memory circuit 100 may be multiplied by the value of the stored bit Q, such as to be read as an output of the memory circuit 100. As depicted in FIG. 1, an INPUT may travel to the memory circuit, while an OUTPUT may be read as output from the memory circuit, such as along the bit line B1. In some embodiments, the INPUT may be an optical signal with an intensity and a wavelength. In some embodiments, the INPUT may be a continuous optical signal. In some embodiments, the INPUT may be a wave packet, including a wave packet with any appropriate wave envelope (for example, Gaussian). In some embodiments, the INPUT may have an intensity (for example, an intensity I1) and a wavelength (for example, a wavelength λ1). In some embodiments, the OUTPUT may have any appropriate continuity, wave packet, wave envelope, etc., which may depend on (e.g., mirror) the properties of the input. In some embodiments, the OUTPUT may have an intensity, such as an intensity I1×Q, which reflects a multiplication of the intensity of the INPUT by the stored bit Q. In some embodiments, the OUPUT may have a wavelength, such as a wavelength λ1, substantially equal to the wavelength of the INPUT.

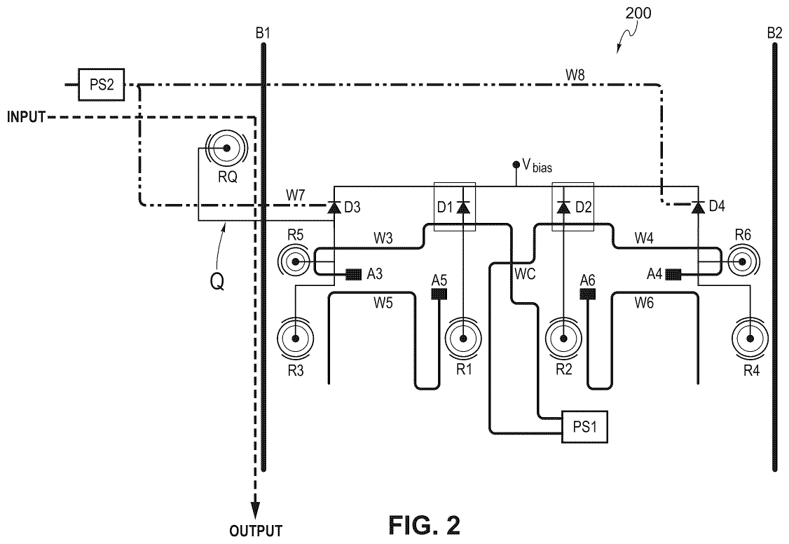

FIG. 2 is a schematic diagram that illustrates an example processing in memory circuit 200 for single bit multiplication for multiple wavelengths, in accordance with one or more embodiments. The memory circuit 200 of FIG. 2 may be configured to provide multi-wavelength read, write, erase, etc. operations. In some embodiments, the memory circuit 200 may be configured for single bit (e.g., 1 bit) multiplication for multiple wavelengths. If the value of the stored bit is zero, single bit operation may be the same as non-multiplicative read, write, erase, etc. operations. Likewise, if the value of the stored bit is one (1), single bit operation may be the same may be the same as non-multiplicative read, write, erase, etc. In some embodiments, the memory circuit 200 may be substantially identical to the memory circuit 100 of FIG. 1. In some embodiments, the memory circuit 200 may have one or more different configuration from the memory circuit 100 of FIG. 1, such as configured for multiple wavelength operation.

In some embodiments, an input supplied to the memory circuit 200, such as by the photosource PS2, may be configured to determine the value of the stored bit Q. In some embodiments, multiple inputs supplied to the memory circuit 200 may be multiplied by the value of the stored bit Q, including concurrently, such as to be read as an output of the memory circuit 200, to provide one or more computation, etc. As depicted in FIG. 2, an INPUT may travel to the memory circuit, while an OUTPUT may be read as output from the memory circuit, such as along the bit line B1. The INPUT may contain multiple inputs, including concurrently, sequentially, etc. In some embodiments, the INPUT may be an optical signal consisting of multiple wavelengths, including of multiplexed wavelengths, each with an intensity and a wavelength. In some embodiments, the INPUT may be one or more continuous optical signals. In some embodiments, the INPUT may be one or more wave packets, including wave packets with any appropriate wave envelope (for example, Gaussian). In some embodiments, the INPUT may have a set of intensities (for example, an intensity I1, I2, I3, etc.) for each wavelength (for example, respectively, for a wavelength λ1, a wavelength λ2, a wavelength λ3, etc.). The wavelengths λ1, λ2, λ3, etc. may have any appropriate wavelength separation. In some embodiments, lhe wavelengths λ1, λ2, λ3, etc. may not be multiples of one another (e.g., harmonic with one another). In some embodiments, the wavelengths λ1, λ2, λ3, etc., may have a wavelength separation such that their wave envelopes do not significantly overlap, such as a wavelength separation of more than a bandwidth, much greater than a bandwidth, much greater than a full width half max (FWHM) of the wave envelope, etc. In some embodiments, the OUTPUT may have any appropriate continuity, wave packet(s), wave envelope(s), etc., which may depend on (e.g., mirror) the properties of the input. In some embodiments, the OUTPUT may have an intensity for each wavelength, such as an intensity I1×Q for the wavelength λ1, an intensity I2×Q for the wavelength λ2, an intensity I3×Q for the wavelength λ3, etc., which reflects a multiplication of the intensity each of the INPUT wavelengths by the stored bit Q. In some embodiments, the OUPUT may have one or more wavelengths, such as wavelength λ1, wavelength λ2, wavelength λ3, etc., substantially equal to the wavelength of the INPUT. In some embodiments, the memory circuit 200 may operate independently on each INPUT wavelength as previously described for the single wavelength operation of memory circuit 100 of FIG. 1. Although three wavelengths are specifically discussed, the memory circuit 200 may operate on up to N wavelengths, where N is any appropriate number of wavelengths which fall within the operating bandwidth of the memory circuit 200.

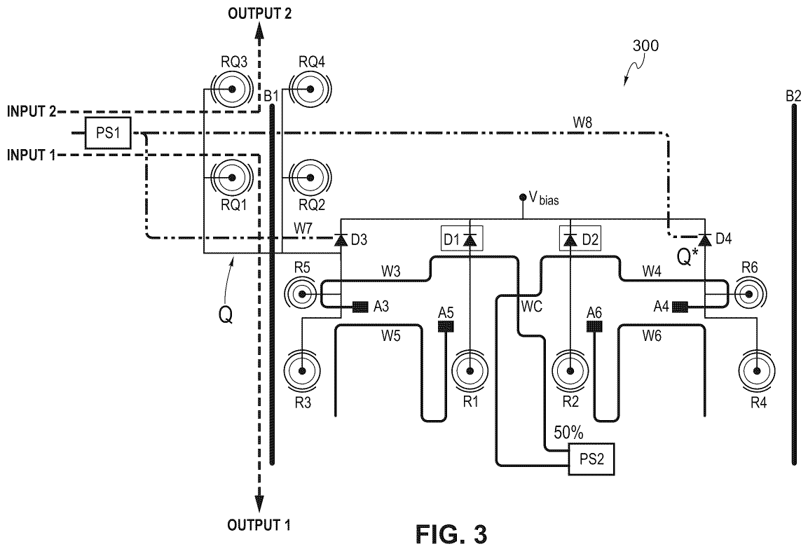

FIG. 3 is a schematic diagram that illustrates an example processing in memory circuit 300 for single bit multiplication for multiple wavelengths with multiple compute elements, in accordance with one or more embodiments. The memory circuit 300 of FIG. 3 may be configured to provide multi-wavelength read, write, erase, etc. operations. In some embodiments, the memory circuit 300 may be configured for single bit (e.g., 1 bit) multiplication for multiple wavelengths. If the value of the stored bit is zero, single bit operation may be the same as non-multiplicative read, write, erase, etc. operations. Likewise, if the value of the stored bit is one (1), single bit operation may be the same may be the same as non-multiplicative read, write, erase, etc. In some embodiments, the memory circuit 300 may be substantially identical to the memory circuit 100 of FIG. 1 and the memory circuit 200 of FIG. 2. In some embodiments, the memory circuit 300 may have one or more different configurations from the memory circuit 100 of FIG. 1 and the memory circuit 200 of FIG. 2, such as configured for multiple wavelength operation.

In some embodiments, the memory circuit 300 may have, including instead of the resonator RQ described in relation to the memory circuit 100 of FIG. 1, a set of resonators RQ1, RQ2, RQ3, and RQ4. Each of the set of resonators RQ1, RQ2, RQ3, and RQ4 may be optically connected to the bit line B1. Each of the set of resonators RQ1, RQ2, RQ3, and RQ4 may be one or more resonators which couples a bit stored in the memory circuit 300 (e.g., a bit Q, which may be stored as charge, frequency, intensity, etc.) to the bit line B1. The resonators RQ1, RQ2, RQ3, and RQ4 may have the same or different dimensions and geometries. In some embodiments, the resonators RQ1, RQ2, RQ3, and RQ4 may select, from the output which may travel along the bit line B1, various wavelengths for transmission in different directions or to different processing paths. For example, the set of resonators RQ1, RQ2, RQ3, and RQ4 may be used to increase throughput for the memory circuit 300 (such as relative to the memory circuit 200 of FIG. 2, which is not to imply that the throughput of said memory circuit is deficient in any way).

For example, in some embodiments, an input supplied to the memory circuit 300, such as by the photosource PS2, may be configured to determine the value of the stored bit Q. In some embodiments, multiple inputs supplied to the memory circuit 200 may be multiplied by the value of the stored bit Q, including concurrently, such as to be read as an output of the memory circuit 300, to provide one or more computation, etc. As depicted in FIG. 3, an input, which may consists of an INPUT1 and an INPUT2, may travel to the memory circuit, while an OUTPUT1 and an OUTPUT2 may be read as output from the memory circuit, such as along the bit line B1. INPUT1 and INPUT2 are depicted distinctly for ease of describing their corresponding output, but may be input along the same line (e.g., by the photosource PS2 along the waveguide W8), including concurrently or sequentially. In some embodiments, the input of INPUT1 and INPUT2 may be an optical signal consisting of multiple wavelengths, including of multiplexed wavelengths, each with an intensity and a wavelength. In some embodiments, the input of INPUT1 and INPUT2 may be one or more continuous optical signals. In some embodiments, the input of INPUT1 and INPUT2 may be one or more wave packets, including wave packets with any appropriate wave envelope (for example, Gaussian). In some embodiments, the input of INPUT1 and INPUT2 may have a set of intensities (for example, an intensity I1, I2, I3, etc.) for each wavelength (for example, respectively, for a wavelength λ1, a wavelength λ2, . . . , a wavelength λN). The wavelengths λ1, λ2, . . . , λN may have any appropriate wavelength separation. The memory circuit 300 may operate on up to N wavelengths, where N is any appropriate number of wavelengths which fall within the operating bandwidth of the memory circuit 300. In some embodiments, the wavelengths λ1, λ2, . . . , λN may not be multiples of one another (e.g., harmonic with one another). In some embodiments, the wavelengths λ1, λ2, . . . , λN may have a wavelength separation such that their wave envelopes do not significantly overlap, such as a wavelength separation of more than a bandwidth, much greater than a bandwidth, much greater than a full width half max (FWHM) of the wave envelope, etc. In some embodiments, from the input of INPUT1 and INPUT2, which output of the memory circuit 300 is delivered to which output (e.g., which input wavelength input of INPUT1 and INPUT2 leads to an output which is produced as which of OUTPUT1 or OUPUT2) is determined by the set of resonators RQ1, RQ2, RQ3, and RQ4. For example, the set of resonators RQ1, RQ2, RQ3, and RQ4 may select some wavelengths for delivery to one or another of the output locations. For example, in the depicted example, the resonators RQ1 may select OUTPUT1, which corresponds to the INPUT1 portion of the input, for delivery to the bit line B1 towards the lower side of the memory circuit 300 and the resonators RQ3 may select OUTPUT2, which corresponds to the INPUT2 portion of the input, for delivery to the bit line B1 towards the upper side of the memory circuit 300. Others of the set of resonators RQ1, RQ2, RQ3, and RQ4 may act as filters, including directional filters, to select portions of the output for deliver to one or more bit line, bit bar line, word line, etc. In some embodiments, the OUTPUT1 and the OUTPUT2 may have any appropriate continuity, wave packet(s), wave envelope(s), etc., which may depend on (e.g., mirror) the properties of the input. In some embodiments, the OUTPUT1 and the OUTPUT2 may have an intensity for each wavelength of the output, such as an intensity I1×Q for the wavelength λ1, an intensity I2×Q for the wavelength λ2, . . . , an intensity IN×Q for the wavelength λN, etc., which reflects a multiplication of the intensity each of the INPUT wavelengths by the stored bit Q. In some embodiments, the OUPUT1 and the OUTPUT2 may have one or more wavelengths, such as wavelength λ1, wavelength λ2, . . . , wavelength λN, substantially equal to the wavelength of the input of INPUT1 and INPUT2. In some embodiments, the memory circuit 300 may operate independently on each INPUT wavelength as previously described for the single wavelength operation of memory circuit 100 of FIG. 1 and the multi wavelength operation of memory circuit 200 of FIG. 2. Which wavelengths correspond to which outputs (e.g., of OUTPUT1 and OUPUT2) may be arbitrary. For example, for some embodiments, the configuration of the set of resonators RQ1, RQ2, RQ3, and RQ4 may operate such that the first 1 to N/2 wavelengths are delivered to OUTPUT2, while the second half of the wavelengths (e.g., wavelengths N/2+1 to N) are delivered to OUTPUT1. Any other appropriate division of wavelengths between OUTPUT1 and OUTPUT2 may be used.

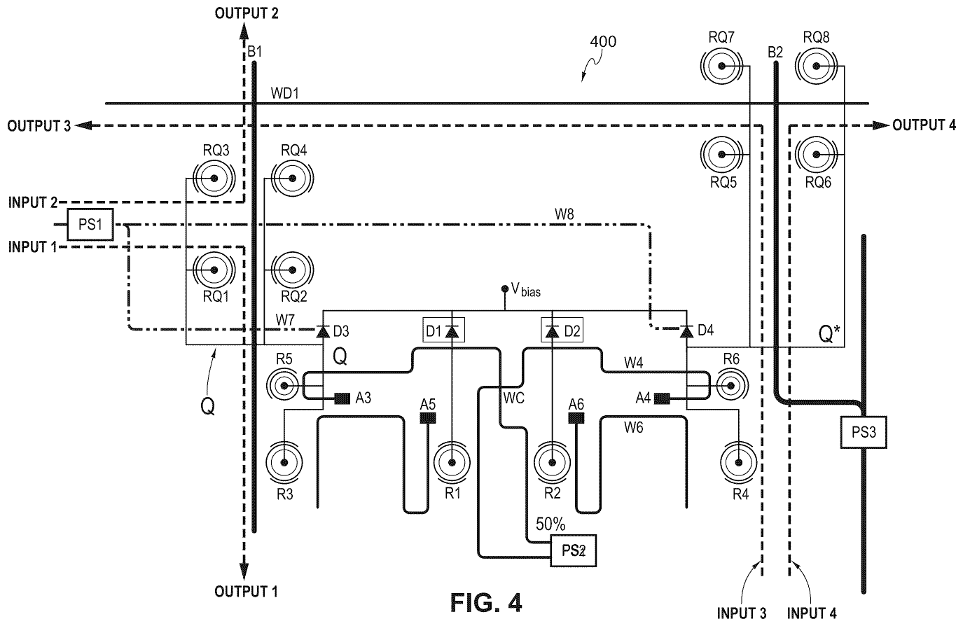

FIG. 4 is a schematic diagram that illustrates an example processing in memory circuit 400 for single bit multiplication for multiple wavelengths with multiple compute elements on both bit line and inverse bit line (bit bar line), in accordance with one or more embodiments. The memory circuit 400 of FIG. 4 may be configured to provide multi-wavelength read, write, erase, etc. operations. In some embodiments, the memory circuit 400 may be configured for single bit (e.g., 1 bit) multiplication for multiple wavelengths, including from multiple input locations. If the value of the stored bit is zero, single bit operation may be the same as non-multiplicative read, write, erase, etc. operations. Likewise, if the value of the stored bit is one (1), single bit operation may be the same may be the same as non-multiplicative read, write, erase, etc. In some embodiments, the memory circuit 400 may be substantially identical to the memory circuit 100 of FIG. 1, the memory circuit 200 of FIG. 2, and the memory circuit 300 of FIG. 3. In some embodiments, the memory circuit 400 may have one or more different configurations from the memory circuit 100 of FIG. 1, the memory circuit 200 of FIG. 2, and the memory circuit 300 of FIG. 3, such as configured for multiple input operations.

In some embodiments, the memory circuit 400 may have, including in addition to the set of resonators RQ1, RQ2, RQ3, and RQ4 described in relation to the memory circuit 300 of FIG. 3, a set of resonators RQ5, RQ6, RQ7, and RQ8. Each of the set of resonators RQ5, RQ6, RQ7, and RQ8 may be optically connected to the bit bar line B2. Each of the set of resonators RQ5, RQ6, RQ7, and RQ8 may be one or more resonators which couples a bit stored in the memory circuit 300 (e.g., a bit Q*, which may be stored as charge, frequency, intensity, etc.) to the bit line B2. In some embodiments, each of the set of resonators RQ5, RQ6, RQ7, and RQ8 may be one or more resonator which couples a bit stored in the memory circuit 300 (e.g., the bit Q*, which may be stored as charge, frequency, intensity, etc.) to a word line WD1. The resonators RQ5, RQ6, RQ7, and RQ8 may have the same or different dimensions and geometries. In some embodiments, the resonators RQ5, RQ6, RQ7, and RQ8 may select, from the output which may travel along the bit bar line B2, various wavelengths for transmission in different directions or to different processing paths, such as along the word line WD1. For example, the set of resonators RQ5, RQ6, RQ7, and RQ8 may be used to increase throughput for the memory circuit 400 (such as relative to the memory circuit 200 of FIG. 2 and the memory circuit 300 of FIG. 3, which is not to imply that the throughput of said memory circuit is deficient in any way). In some embodiments, the

For example, in some embodiments, an input supplied to the memory circuit 400, such as by a photosource PS3 or along the bit bar line B2, may be configured to determine the value of the stored bit Q*. In some embodiments, the input supplied by the photosource PS3 (e.g., an INPUT3 and an INPUT4) may be in addition to the input supplied by the photosource PS2 (e.g., the INPUT1 and INTPU2 which may generate corresponding output such as OUTPUT1 and OUTPUT2 as previously described with respect to memory circuit 300 FIG. 3). In some embodiments, multiple inputs supplied to the memory circuit 400 may be multiplied by the value of the stored bit Q*, including concurrently, such as to be read as an output of the memory circuit 400, to provide one or more computation, etc. As depicted in FIG. 4, an input of INPUT3 and INPUT4 may travel to the memory circuit, while an OUTPUT3 and an OUTPUT4 may be read as output from the memory circuit, such as along the bit bar line B1 or the word line WD1. In some embodiments, the input of INPUT3 and INPUT4 may be an optical signal consisting of multiple wavelengths, including of multiplexed wavelengths, each with an intensity and a wavelength. In some embodiments, the input of INPUT3 and INPUT4 may be one or more continuous optical signals. In some embodiments, the input of INPUT3 and INPUT4 may be one or more wave packets, including wave packets with any appropriate wave envelope (for example, Gaussian). In some embodiments, the input of INPUT3 and INPUT4 may have a set of intensities (for example, an intensity J1, J2, J3, etc.) for each wavelength (for example, respectively, for a wavelength λ1, a wavelength λ2, . . . , a wavelength λN—which may be the same or different that the wavelengths of the input of INPUT3 and INPUT4 as previously described in relation to memory circuit 300 of FIG. 3). The wavelengths λ1, λ2, . . . , λN may have any appropriate wavelength separation. The memory circuit 400 may operate on up to N wavelengths, where N is any appropriate number of wavelengths which fall within the operating bandwidth of the memory circuit 400. In some embodiments, the wavelengths λ1, λ2, . . . , λN may not be multiples of one another (e.g., harmonic with one another). In some embodiments, the wavelengths λ1, λ2, . . . , λN may have a wavelength separation such that their wave envelopes do not significantly overlap, such as a wavelength separation of more than a bandwidth, much greater than a bandwidth, much greater than a full width half max (FWHM) of the wave envelope, etc. In some embodiments, from the input of INPUT3 and INPUT4, which output of the memory circuit 400 is delivered to which output (e.g., which input wavelength leads to an output which is produced as which of OUTPUT3 or OUPUT4) is determined by the set of resonators RQ5, RQ6, RQ7, and RQ8. For example, the set of resonators RQ5, RQ6, RQ7, and RQ8 may select some wavelengths for delivery to one or another of the output locations. For example, in the depicted example, the resonators RQ5 may select OUTPUT3, which corresponds to the INPUT3 portion of the input, for delivery to the word line WD1 towards the left side of the memory circuit 400 and the resonators RQ6 may select OUTPUT4, which corresponds to the INPUT4 portion of the input, for delivery to the word line WD1 towards the right side of the memory circuit 400. Others of the set of resonators RQ5, RQ6, RQ7, and RQ8 may act as filters, including directional filters, to select portions of the output for deliver to one or more bit line, bit bar line, word line, etc. In some embodiments, the OUTPUT3 and the OUTPUT4 may have any appropriate continuity, wave packet(s), wave envelope(s), etc., which may depend on (e.g., mirror) the properties of the input. In some embodiments, the OUTPUT3 and the OUTPUT4 may have an intensity for each wavelength of the output, such as an intensity J1×Q for the wavelength λ1, an intensity J2×Q for the wavelength λ2, . . . , an intensity JN×Q for the wavelength λN, etc., which reflects a multiplication of the intensity each of the input of INPUT3 and INPUT4 wavelengths by the stored bit Q*. In some embodiments, the stored bit Q* may be of the same size, but opposite magnitude, as the stored bit Q. In some embodiments, the OUPUT3 and the OUTPUT4 may have one or more wavelengths, such as wavelength λ1, wavelength λ2, . . . , wavelength λN, substantially equal to the wavelength of the input of INPUT3 and INPUT4. In some embodiments, the memory circuit 400 may operate independently on each input of INPUT3 and INPUT4 wavelength as previously described for the single wavelength operation of memory circuit 100 of FIG. 1, the multi wavelength operation of memory circuit 200 of FIG. 2, and the multi wavelength operation of memory circuit 300 of FIG. 3. Which wavelengths correspond to which outputs (e.g., of OUTPUT3 and OUPUT4) may be arbitrary. For example, for some embodiments, the configuration of the set of resonators RQ5, RQ6, RQ7, and RQ8 may operate such that the first 1 to N/2 wavelengths are delivered to OUTPUT3, while the second half of the wavelengths (e.g., wavelengths N/2+1 to N) are delivered to OUTPUT4. Any other appropriate division of wavelengths between OUTPUT3 and OUTPUT4 may be used.

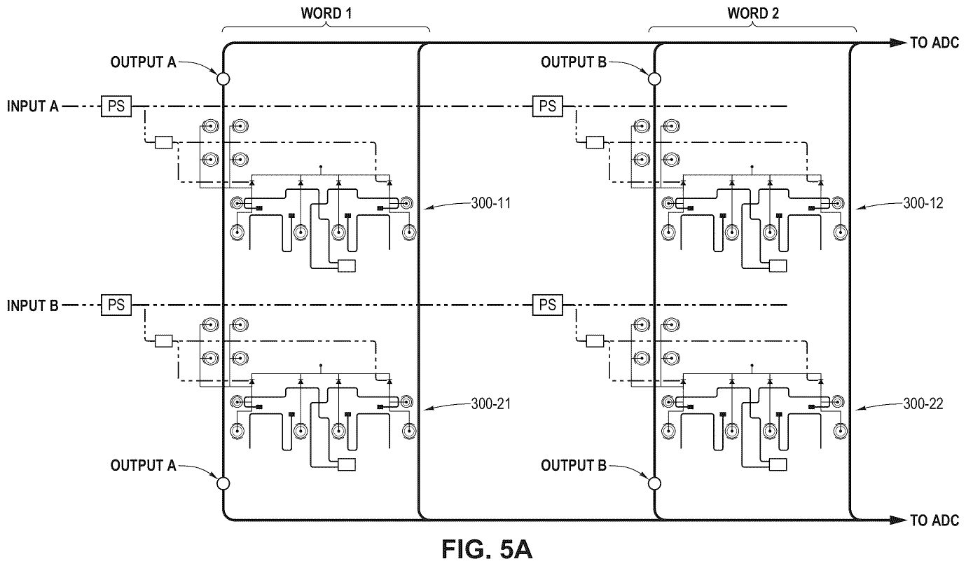

FIG. 5A is a schematic diagram that illustrates an example processing in memory circuit for multi-wavelength, multi-bit convolution, in accordance with one or more embodiments. FIG. 5A depicts an array of memory circuits. As depicted, FIG. 5A depicts an array of memory circuits substantially identical to memory circuit 300 of FIG. 3, but it should be understood that any appropriate memory circuit as previously described may be found in the array. The memory circuits of the array may or may not be substantially identical with one another.

The memory circuits of the array are labeled 300-11 and 300-21, for the first and second memory circuits in the first column of the array, and 300-12 and 300-22, for the first and second memory circuits in the second column of the array. This labeling is provided for ease of description only, and more or fewer memory circuits may be provided in the array. In some embodiments, each element of the array may store a different value (corresponding to the stored bit Q described in relation to memory circuit 300 of FIG. 3). For example, memory circuit 300-11 may store bit Q11, memory circuit 300-21 may store bit Q21, memory circuit 300-12 may store bit Q12, and memory circuit 300-22 may store bit Q22. Additional memory circuits may store corresponding bits, which may be written in any appropriate manner.

An INPUTA is provided along a first input line (e.g., corresponding to the first row of the array) and an INPUTB is provided along a second input line (e.g., corresponding to the second row of the array). Other inputs, including different inputs along additional rows, may be provided. In some embodiments, the INPUTA may be substantially identical to the INPUTB. In some embodiments, the INPUTA may be different from the INPUTB. Each input may contain multiple wavelengths at multiple intensities. For example, INPUTA may consist of multiple wavelengths with corresponding intensities, such as wavelength λ1, wavelength λ2, . . . , wavelength λN with intensities I11, I12, . . . , I1N. INPUTB may consist of multiple wavelengths with corresponding intensities, such as wavelength λ1, wavelength λ2, . . . , wavelength λN with intensities I21, I22, . . . , I2N. The combination of memory circuits in the first row (e.g., memory circuits 300-11 and 300-21) may then operate to perform a convolution operation with an output (e.g., OUTPUTA) intensity substantially equal to (I11×Q11)+(I21×Q21)+ . . . (IN1×QN1) for wavelength λ1, substantially equal to (I12×Q11)+(I22×Q21)+ . . . (IN2×QN1) for wavelength λ2, and substantially equal to (I1N×Q11)+(12N×Q21)+. . . (INN×QN1) for wavelength λN, where there are N input wavelengths and N memory cells in the row (although the number of input wavelengths and the number of memory cells in a row may be different. While only one row is depicted in Word1, there may be multiple rows. In such a case, the first row (e.g., as depicted) may correspond to the most significant bit (MSB) in the convolution. The output of all the rows (e.g., of all the memory circuits in each row) may be added to generate a convolution output for Word 1. Likewise, the combination of memory circuits in the first row of the second word Word2 (e.g., memory circuits 300-12 and 300-22) may then operate to perform a convolution operation with an output (e.g., OUTPUTB) substantially equal to (I11×Q12)+(I21×Q22)+ . . . (IN1×QN2) for wavelength λ1, substantially equal to (I12×Q12)+(I22×Q22)+ . . . (IN2×QN2) for wavelength λ2, and substantially equal to (IIN×Q12)+(12N×Q22)+ . . . (INN×QN2) for wavelength λN, where there are N input wavelengths and N memory cells in the row (although the number of input wavelengths and the number of memory cells in a row may be different. While only one row is depicted in Word2, there may be multiple rows. In such a case, the seond row (e.g., as depicted) may correspond to the MSB in the convolution. The output of all the rows (e.g., of all the memory circuits in each row) may be added to generate a convolution output for Word 1.

FIG. 5B is a schematic diagram that illustrates a representative computing schematic, in accordance with one or more embodiments. FIG. 5B depicts an array, in which each square may represent a memory elements. The array may be of any appropriate size, such as consisting of 256 columns, divided into 32 8 column words. Likewise, the array may consist of 256 rows, divided into any appropriate segments. Each row of the array may receive an input of multiple wavelengths with multiple intensities. Each memory circuit may operate on the multiple input wavelengths it receives to generate a multi-wavelength multiplication. The output of each column of memory circuits may be summed to generate a convolution of the multiple wavelength multiplication outputs. Although representative columns, rows, words, etc. are depicted, any appropriate array may be used.

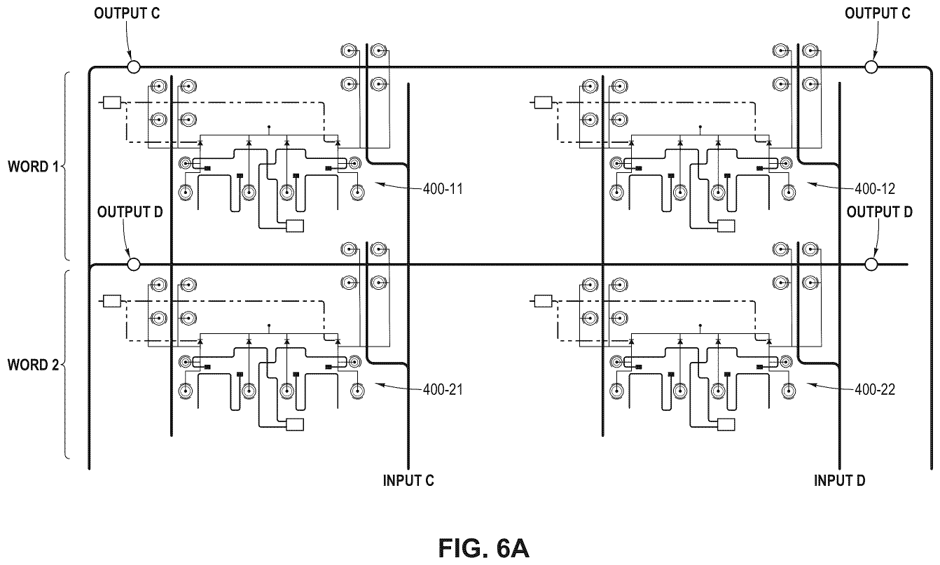

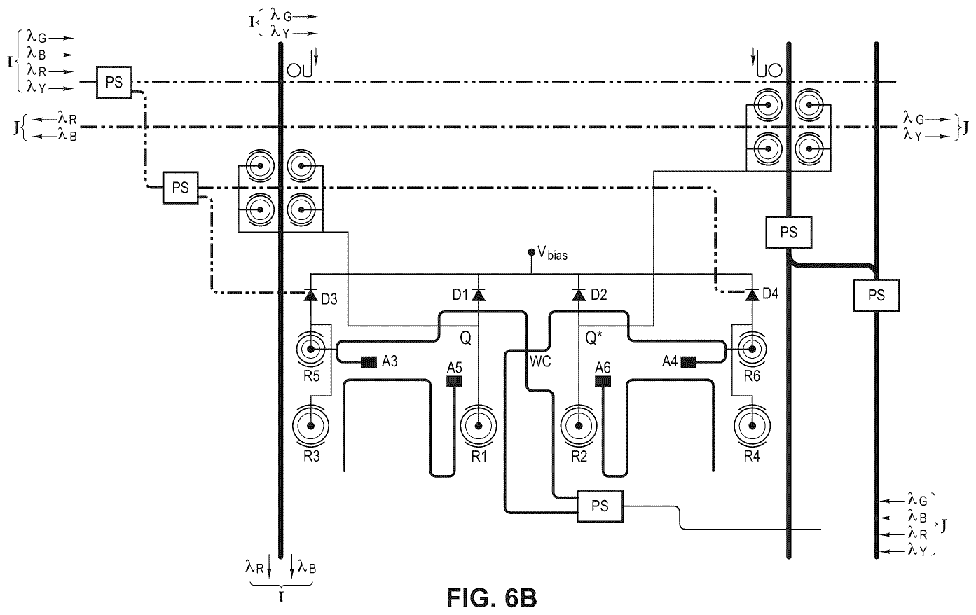

FIG. 6A is a schematic diagram that illustrates an example processing in memory circuit for multi-wavelength, multi-bit convolution and transposition, in accordance with one or more embodiments. FIG. 6A depicts an array of memory circuits. As depicted, FIG. 6A depicts an array of memory circuits substantially identical to memory circuit 400 of FIG. 4, but it should be understood that any appropriate memory circuit as previously described may be found in the array. The memory circuits of the array may or may not be substantially identical with one another.

The memory circuits of the array are labeled 400-11 and 400-21, for the first and second memory circuits in the first column of the array, and 400-12 and 400-22, for the first and second memory circuits in the second column of the array. This labeling is provided for ease of description only, and more or fewer memory circuits may be provided in the array. In some embodiments, each element of the array may store a different value (corresponding to the stored bit Q or the stored bit Q* described in relation to memory circuit 400 of FIG. 4). For example, memory circuit 400-11 may store bit Q11, memory circuit 400-21 may store bit Q21, memory circuit 400-12 may store bit Q12, and memory circuit 400-22 may store bit Q22. Additional memory circuits may store corresponding bits, which may be written in any appropriate manner.

An INPUTC is provided along a first bit bar line (e.g., corresponding to the first row of the array) and an INPUTD is provided along a second bit bar line (e.g., corresponding to the second row of the array). Other inputs, including different inputs along additional rows, may be provided. In some embodiments, the INPUTC may be substantially identical to the INPUTD. In some embodiments, the INPUTC may be different from the INPUTD. Each input may contain multiple wavelengths at multiple intensities. For example, INPUTC may consist of multiple wavelengths with corresponding intensities, such as wavelength λ1, wavelength λ2, . . . , wavelength λN with intensities J11, J12, . . . , J1N. INPUTD may consist of multiple wavelengths with corresponding intensities, such as wavelength λ1, wavelength λ2, . . . , wavelength λN with intensities J21, J22, . . . ,J2N. The combination of memory circuits in the first column (e.g., memory circuits 300-11 and 300-12) may then operate to perform a convolution transpose operation with an output (e.g., OUTPUTC) intensity substantially equal to (I11×Q11)+(I21×Q12)+ . . . (IN1×Q1N) for wavelength λ1, substantially equal to (I12×Q11)+(I22×Q12)+ . . . (IN2×Q1N) for wavelength λ2, and substantially equal to (I1N×Q11)+(I2N×Q12)+ . . . (INN×Q1N) for wavelength λN, where there are N input wavelengths and N memory cells in the column (although the number of input wavelengths and the number of memory cells in a column may be different. While only one column is depicted in Word1, there may be multiple column. In such a case, the first column (e.g., as depicted) may correspond to the most significant bit (MSB) in the convolution. The output of all the columns (e.g., of all the memory circuits in each column) may be added to generate a convolution transpose output for Word 1. Likewise, the combination of memory circuits in the first column of the second word Word2 (e.g., memory circuits 300-21 and 300-22) may then operate to perform a convolution operation with an output (e.g., OUTPUTD) substantially equal to (I11×Q21)+(I21×Q22)+ . . . (IN1×Q2N) for wavelength λ1, substantially equal to (I12×Q21)+(I22×Q22)+ . . . (IN2×Q2N) for wavelength λ2, and substantially equal to (I1N×Q21)+(I2N×Q22)+ . . . (INN×Q2N) for wavelength λN, where there are N input wavelengths and N memory cells in the column (although the number of input wavelengths and the number of memory cells in a column may be different. While only one column is depicted in Word2, there may be multiple columns. In such a case, the second column (e.g., as depicted) may correspond to the MSB in the convolution. The output of all the columns (e.g., of all the memory circuits in each column) may be added to generate a convolution output for Word 1.

FIG. 6B is a schematic diagram that illustrates an example processing in memory circuit for a combined convolution and transposition operation, in accordance with one or more embodiments. FIG. 6B depicts a memory circuit that stores a bit Q and bit complement Q*. The memory circuit contains active microring resonators R1, R2, R3, R4, R5, and R6. The memory circuit accepts wavelengths λc for control, λbit for bit, and λwrite for write. The memory circuit contains absorbers A1, A2, A3, A4, A5, and A6. The memory circuit contains multiple selecting resonators resonant to green (at λG), blue (at λB), red (at λR), and yellow (at λY) wavelengths. The memory circuit accepts a horizonal, multi-bit input, corresponding to I(λG, λB, λR, and λY) and a vertical multi-bit input, corresponding to J(λG, λB, λR, and λY). The resonators select different outputs to output at different locations, as depicted.

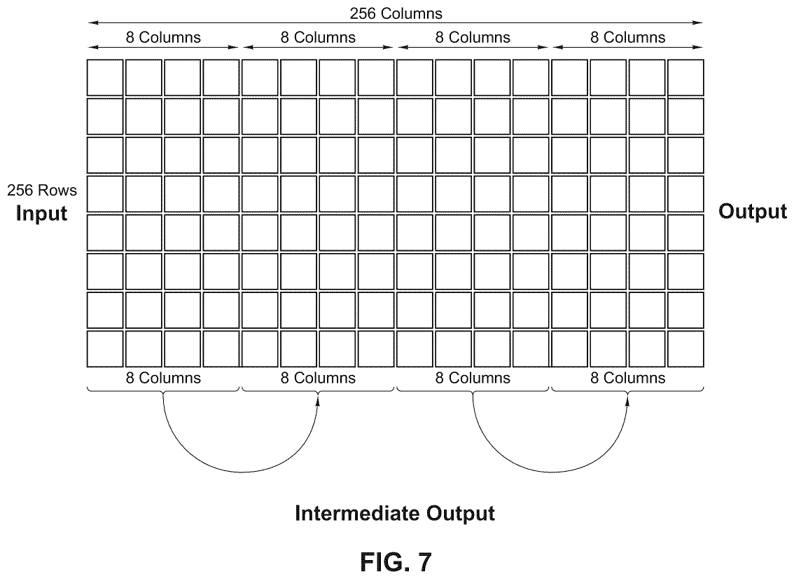

FIG. 7 is a schematic diagram that illustrates a representative computing schematic for a word-interleaved multi-matrix MAC operation, in accordance with one or more embodiments. FIG. 7 depicts an array, in which each square may represent a memory elements. The array may be of any appropriate size, such as consisting of 256 columns, divided into 32 8 column words. Likewise, the array may consist of 256 rows, divided into any appropriate segments. Each row of the array may receive an input of multiple wavelengths with multiple intensities. Each memory circuit may operate on the multiple input wavelengths it receives to generate a multi-wavelength multiplication. The output of each column of memory circuits may be summed to generate a convolution of the multiple wavelength multiplication outputs. Although representative columns, rows, words, etc. are depicted, any appropriate array may be used.

For example, an input for a first row may be I11 at λ1, I12 and λ2, . . . . I1X at λX, while an input for row N may be IN1 at λ1, IN2 and λ2, . . . . INX at λX. An intermediate output may then be generated, based on the stored Q values for each element of the array, such as (I11×Q11)+(I21×Q21)+. . . (IN1×Qn1) through (I1X×Q11)+(12X×Q21)+ . . . (INX×QN1) . For a second word, the intermediate output may be (I12×Q12)+(I22×Q22)+ . . . (IN2×QN2) through (I1X×Q12)+(I2X×Q21)+. . . (INX×QN2). Another operation may then be performed to generate the multi-matric MAC operation with word interleaving, which may generate the final output.

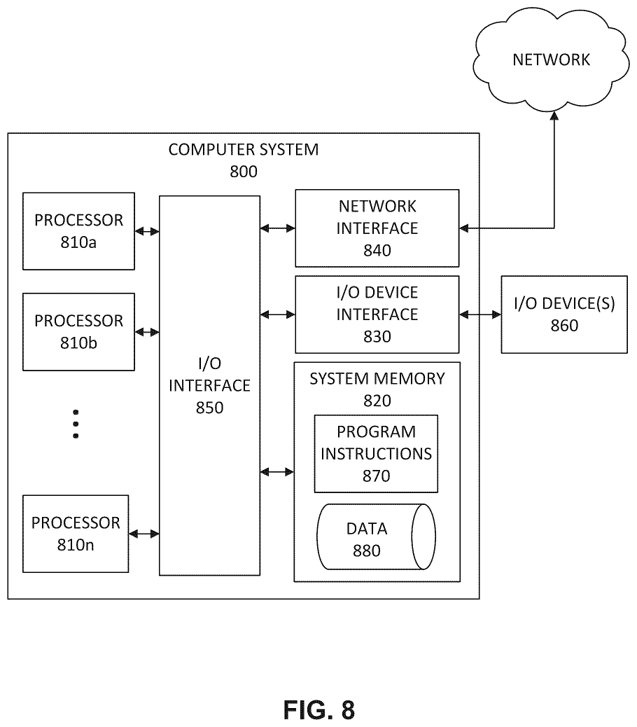

FIG. 8 is a diagram that illustrates an exemplary computing system 800, in accordance with some embodiments. Various portions of systems and methods described herein may include or be executed on one or more computer systems similar to computing system 800. Further, processes and modules described herein may be executed by one or more processing systems similar to that of computing system 800.

Computing system 800 may include one or more processors (e.g., processors 810a-810n) coupled to system memory 820, an input/output (I/O) device interface 830, and a network interface 840 via an input/output (I/O) interface 850. A processor may include a single processor or a plurality of processors (e.g., distributed processors). A processor may be any suitable processor capable of executing or otherwise performing instructions. A processor may include a central processing unit (CPU) that carries out program instructions to perform the arithmetical, logical, and input/output operations of computing system 800. A processor may execute code (e.g., processor firmware, a protocol stack, a database management system, an operating system, or a combination thereof) that creates an execution environment for program instructions. A processor may include a programmable processor. A processor may include general or special purpose microprocessors. A processor may receive instructions and data from a memory (e.g., system memory 820). Computing system 800 may be a units-processor system including one processor (e.g., processor 810a), or a multi-processor system including any number of suitable processors (e.g., 810a-810n). Multiple processors may be employed to provide for parallel or sequential execution of one or more portions of the techniques described herein. Processes, such as logic flows, described herein may be performed by one or more programmable processors executing one or more computer programs to perform functions by operating on input data and generating corresponding output. Processes described herein may be performed by, and apparatus may also be implemented as, special purpose logic circuitry, e.g., an FPGA (field programmable gate array) or an ASIC (application specific integrated circuit). Computing system 800 may include a plurality of computing devices (e.g., distributed computer systems) to implement various processing functions.

I/O device interface 830 may provide an interface for connection of one or more I/O devices 860 to computing system 800. I/O devices may include devices that receive input (e.g., from a user) or output information (e.g., to a user). I/O devices 860 may include, for example, graphical user interface presented on displays (e.g., a cathode ray tube (CRT) or liquid crystal display (LCD) monitor), pointing devices (e.g., a computer mouse or trackball), keyboards, keypads, touchpads, scanning devices, voice recognition devices, gesture recognition devices, printers, audio speakers, microphones, cameras, or the like. I/O devices 860 may be connected to computing system 800 through a wired or wireless connection. I/O devices 860 may be connected to computing system 800 from a remote location. I/O devices 860 located on remote computer system, for example, may be connected to computing system 800 via a network and network interface 840.

Network interface 840 may include a network adapter that provides for connection of computing system 800 to a network. Network interface 840 may facilitate data exchange between computing system 800 and other devices connected to the network. Network interface 840 may support wired or wireless communication. The network may include an electronic communication network, such as the Internet, a local area network (LAN), a wide area network (WAN), a cellular communications network, or the like.

System memory 820 may be configured to store program instructions 870 or data 880. Program instructions 870 may be executable by a processor (e.g., one or more of processors 810a-810n) to implement one or more embodiments of the present techniques. Program instructions 870 may include modules of computer program instructions for implementing one or more techniques described herein with regard to various processing modules. Program instructions may include a computer program (which in certain forms is known as a program, software, software application, script, or code). A computer program may be written in a programming language, including compiled or interpreted languages, or declarative or procedural languages. A computer program may include a unit suitable for use in a computing environment, including as a stand-alone program, a module, a component, or a subroutine. A computer program may or may not correspond to a file in a file system. A program may be stored in a portion of a file that holds other programs or data (e.g., one or more scripts stored in a markup language document), in a single file dedicated to the program in question, or in multiple coordinated files (e.g., files that store one or more modules, sub programs, or portions of code). A computer program may be deployed to be executed on one or more computer processors located locally at one site or distributed across multiple remote sites and interconnected by a communication network.

System memory 820 may include a tangible program carrier having program instructions stored thereon. A tangible program carrier may include a non-transitory computer readable storage medium. A non-transitory computer readable storage medium may include a machine-readable storage device, a machine-readable storage substrate, a memory device, or any combination thereof. Non-transitory computer readable storage medium may include non-volatile memory (e.g., flash memory, ROM, PROM, EPROM, EEPROM memory), volatile memory (e.g., random access memory (RAM), static random-access memory (SRAM), synchronous dynamic RAM (SDRAM)), bulk storage memory (e.g., CD-ROM and/or DVD-ROM, hard-drives), or the like. System memory 820 may include a non-transitory computer readable storage medium that may have program instructions stored thereon that are executable by a computer processor (e.g., one or more of processors 810a-810n) to cause the subject matter and the functional operations described herein. A memory (e.g., system memory 820) may include a single memory device and/or a plurality of memory devices (e.g., distributed memory devices).

I/O interface 850 may be configured to coordinate I/O traffic between processors 810a-810n, system memory 820, network interface 840, I/O devices 860, and/or other peripheral devices. I/O interface 850 may perform protocol, timing, or other data transformations to convert data signals from one component (e.g., system memory 820) into a format suitable for use by another component (e.g., processors 810a-810n). I/O interface 850 may include support for devices attached through various types of peripheral buses, such as a variant of the Peripheral Component Interconnect (PCI) bus standard or the Universal Serial Bus (USB) standard.

Embodiments of the techniques described herein may be implemented using a single instance of computing system 800 or multiple computer systems 800 configured to host different portions or instances of embodiments. Multiple computer systems 800 may provide for parallel or sequential processing/execution of one or more portions of the techniques described herein.

Those skilled in the art will appreciate that computing system 800 is merely illustrative and is not intended to limit the scope of the techniques described herein. Computing system 800 may include any combination of devices or software that may perform or otherwise provide for the performance of the techniques described herein. For example, computing system 800 may include or be a combination of a cloud-computing system, a data center, a server rack, a server, a virtual server, a desktop computer, a laptop computer, a tablet computer, a server device, a client device, a mobile telephone, a personal digital assistant (PDA), a mobile audio or video player, a game console, a vehicle-mounted computer, or a Global Positioning System (GPS), or the like. Computing system 800 may also be connected to other devices that are not illustrated, or may operate as a stand-alone system. In addition, the functionality provided by the illustrated components may in some embodiments be combined in fewer components or distributed in additional components. Similarly, in some embodiments, the functionality of some of the illustrated components may not be provided or other additional functionality may be available.

Those skilled in the art will also appreciate that while various items are illustrated as being stored in memory or on storage while being used, these items or portions of them may be transferred between memory and other storage devices for purposes of memory management and data integrity. Alternatively, in other embodiments some or all of the software components may execute in memory on another device and communicate with the illustrated computer system via inter-computer communication. Some or all of the system components or data structures may also be stored (e.g., as instructions or structured data) on a computer-accessible medium or a portable article to be read by an appropriate drive, various examples of which are described above. In some embodiments, instructions stored on a computer-accessible medium separate from computing system 800 may be transmitted to computing system 800 via transmission media or signals such as electrical, electromagnetic, or digital signals, conveyed via a communication medium such as a network or a wireless link. Various embodiments may further include receiving, sending, or storing instructions or data implemented in accordance with the foregoing description upon a computer-accessible medium. Accordingly, the present disclosure may be practiced with other computer system configurations.

In block diagrams, illustrated components are depicted as discrete functional blocks, but embodiments are not limited to systems in which the functionality described herein is organized as illustrated. The functionality provided by each of the components may be provided by software or hardware modules that are differently organized than is presently depicted, for example such software or hardware may be intermingled, conjoined, replicated, broken up, distributed (e.g., within a data center or geographically), or otherwise differently organized. The functionality described herein may be provided by one or more processors of one or more computers executing code stored on a tangible, non-transitory, machine-readable medium. In some cases, third party content delivery networks may host some or all of the information conveyed over networks, in which case, to the extent information (e.g., content) is said to be supplied or otherwise provided, the information may be provided by sending instructions to retrieve that information from a content delivery network.

The reader should appreciate that the present application describes several disclosures. Rather than separating those disclosures into multiple isolated patent applications, applicants have grouped these disclosures into a single document because their related subject matter lends itself to economies in the application process. But the distinct advantages and aspects of such disclosures should not be conflated. In some cases, embodiments address all of the deficiencies noted herein, but it should be understood that the disclosures are independently useful, and some embodiments address only a subset of such problems or offer other, unmentioned benefits that will be apparent to those of skill in the art reviewing the present disclosure. Due to costs constraints, some features disclosed herein may not be presently claimed and may be claimed in later filings, such as continuation applications or by amending the present claims. Similarly, due to space constraints, neither the Abstract nor the Summary sections of the present document should be taken as containing a comprehensive listing of all such disclosures or all aspects of such disclosures.

It should be understood that the description and the drawings are not intended to limit the disclosure to the particular form disclosed, but to the contrary, the intention is to cover all modifications, equivalents, and alternatives falling within the spirit and scope of the present disclosure as defined by the appended claims. Further modifications and alternative embodiments of various aspects of the disclosure will be apparent to those skilled in the art in view of this description. Accordingly, this description and the drawings are to be construed as illustrative only and are for the purpose of teaching those skilled in the art the general manner of carrying out the disclosure. It is to be understood that the forms of the disclosure shown and described herein are to be taken as examples of embodiments. Elements and materials may be substituted for those illustrated and described herein, parts and processes may be reversed or omitted, and certain features of the disclosure may be utilized independently, all as would be apparent to one skilled in the art after having the benefit of this description of the disclosure. Changes may be made in the elements described herein without departing from the spirit and scope of the disclosure as described in the following claims. Headings used herein are for organizational purposes only and are not meant to be used to limit the scope of the description.

As used throughout this application, the word “may” is used in a permissive sense (e.g., meaning having the potential to), rather than the mandatory sense (e.g., meaning must). The words “include”, “including”, and “includes” and the like mean including, but not limited to. As used throughout this application, the singular forms “a,” “an,” and “the” include plural referents unless the content explicitly indicates otherwise. Thus, for example, reference to “an element” or “a element” includes a combination of two or more elements, notwithstanding use of other terms and phrases for one or more elements, such as “one or more.” The term “or” is, unless indicated otherwise, non-exclusive, e.g., encompassing both “and” and “or.” Terms describing conditional relationships, e.g., “in response to X, Y,” “upon X, Y,”, “if X, Y,” “when X, Y,” and the like, encompass causal relationships in which the antecedent is a necessary causal condition, the antecedent is a sufficient causal condition, or the antecedent is a contributory causal condition of the consequent, e.g., “state X occurs upon condition Y obtaining” is generic to “X occurs solely upon Y” and “X occurs upon Y and Z.” Such conditional relationships are not limited to consequences that instantly follow the antecedent obtaining, as some consequences may be delayed, and in conditional statements, antecedents are connected to their consequents, e.g., the antecedent is relevant to the likelihood of the consequent occurring. Statements in which a plurality of attributes or functions are mapped to a plurality of objects (e.g., one or more processors performing steps A, B, C, and D) encompasses both all such attributes or functions being mapped to all such objects and subsets of the attributes or functions being mapped to subsets of the attributes or functions (e.g., both all processors each performing steps A-D, and a case in which processor 1 performs step A, processor 2 performs step B and part of step C, and processor 3 performs part of step C and step D), unless otherwise indicated. Similarly, reference to “a computer system” performing step A and “the computer system” performing step B can include the same computing device within the computer system performing both steps or different computing devices within the computer system performing steps A and B. Further, unless otherwise indicated, statements that one value or action is “based on” another condition or value encompass both instances in which the condition or value is the sole factor and instances in which the condition or value is one factor among a plurality of factors. Unless otherwise indicated, statements that “each” instance of some collection have some property should not be read to exclude cases where some otherwise identical or similar members of a larger collection do not have the property, e.g., each does not necessarily mean each and every. Limitations as to sequence of recited steps should not be read into the claims unless explicitly specified, e.g., with explicit language like “after performing X, performing Y,” in contrast to statements that might be improperly argued to imply sequence limitations, like “performing X on items, performing Y on the X'ed items,” used for purposes of making claims more readable rather than specifying sequence. Statements referring to “at least Z of A, B, and C,” and the like (e.g., “at least Z of A, B, or C”), refer to at least Z of the listed categories (A, B, and C) and do not require at least Z units in each category. Unless specifically stated otherwise, as apparent from the discussion, it is appreciated that throughout this specification discussions utilizing terms such as “processing,” “computing,” “calculating,” “determining” or the like refer to actions or processes of a specific apparatus, such as a special purpose computer or a similar special purpose electronic processing/computing device. Features described with reference to geometric constructs, like “parallel,” “perpendicular/orthogonal,” “square”, “cylindrical,” and the like, should be construed as encompassing items that substantially embody the properties of the geometric construct, e.g., reference to “parallel” surfaces encompasses substantially parallel surfaces. The permitted range of deviation from Platonic ideals of these geometric constructs is to be determined with reference to ranges in the specification, and where such ranges are not stated, with reference to industry norms in the field of use, and where such ranges are not defined, with reference to industry norms in the field of manufacturing of the designated feature, and where such ranges are not defined, features substantially embodying a geometric construct should be construed to include those features within 15% of the defining attributes of that geometric construct. The terms “first”, “second”, “third,” “given” and so on, if used in the claims, are used to distinguish or otherwise identify, and not to show a sequential or numerical limitation. As is the case in ordinary usage in the field, data structures and formats described with reference to uses salient to a human need not be presented in a human-intelligible format to constitute the described data structure or format, e.g., text need not be rendered or even encoded in Unicode or ASCII to constitute text; images, maps, and data-visualizations need not be displayed or decoded to constitute images, maps, and data-visualizations, respectively; speech, music, and other audio need not be emitted through a speaker or decoded to constitute speech, music, or other audio, respectively. Computer implemented instructions, commands, and the like are not limited to executable code and can be implemented in the form of data that causes functionality to be invoked, e.g., in the form of arguments of a function or API call. To the extent bespoke noun phrases (and other coined terms) are used in the claims and lack a self-evident construction, the definition of such phrases may be recited in the claim itself, in which case, the use of such bespoke noun phrases should not be taken as invitation to impart additional limitations by looking to the specification or extrinsic evidence.

The above-described embodiments of the present disclosure are presented for purposes of illustration and not of limitation, and the present disclosure is limited only by the claims which follow. Furthermore, it should be noted that the features and limitations described in any one embodiment may be applied to any other embodiment herein, and flowcharts or examples relating to one embodiment may be combined with any other embodiment in a suitable manner, done in different orders, or done in parallel. In addition, the systems and methods described herein may be performed in real time. It should also be noted that the systems and/or methods described above may be applied to, or used in accordance with, other systems and/or methods.

In this patent filing, to the extent any U.S. patents, U.S. patent applications, or other materials (e.g., articles) have been incorporated by reference, the text of such materials is only incorporated by reference to the extent that no conflict exists between such material and the statements and drawings set forth herein. In the event of such conflict, the text of the present document governs, and terms in this document should not be given a narrower reading in virtue of the way in which those terms are used in other materials incorporated by reference.

The present techniques may be better understood with reference to the following enumerated embodiments:

A1. A memory circuit comprising: a first ring resonator R1 that optically couples a first waveguide W1 to a third waveguide W3, the first ring resonator R1 further electrically coupled to a first diode D1; a second ring resonator R2 that optically couples a second waveguide W2 to a fourth waveguide W4, the second ring resonator R2 further electrically coupled to a second diode D2; a third ring resonator R3 that optically couples the third waveguide W3 to a first bit line B1, the third ring resonator R3 further electrically coupled to a third diode D3; a fourth ring resonator R4 that optically couples the fourth waveguide W4 to a second bit line B2, the fourth ring resonator R4 further electrically coupled to a fourth diode D4; a fifth ring resonator R5 that optically couples the second waveguide W2 to the first bit line B1, the fifth ring resonator R5 further electrically coupled to at least one of the third ring resonator R3 and the third diode D3; and a sixth ring resonator R6 that optically couples the first waveguide W1 to the second bit line B2, the sixth ring resonator R6 further electrically coupled to at least one of the fourth ring resonator R4 and the fourth diode D4.

A2. The memory circuit of embodiment A1, further comprising a compute ring resonator RC optically coupled to the first bit line, the compute ring resonator RC electrically coupled to at least one of the third ring resonator R3, the fifth ring resonator R5, and the third diode D3.

A3. The memory circuit of embodiment A1 or A2, wherein at least one of the first diode D1, the second diode D2, the third diode D3, and the fourth diode D4 is a photodiode.

A4. The memory circuit of embodiment A3, wherein the first waveguide is optically coupled to the second diode D2 and wherein the second waveguide is optically coupled to the first diode D1.

A5. The memory circuit of embodiment A3 or A4, wherein the first diode D1, the second diode D2, the third diode D3, and the fourth diode D4 are electrically coupled.

A6. The memory circuit of embodiment A5, wherein cathodes of the first diode D1, the second diode D2, the third diode D3, and the fourth diode D4 are electrically coupled to a bias voltage source.

A7. The memory circuit of any one of embodiments A3 to A6, wherein an input optical source is optically coupled to at least one of the third diode D3 and the fourth diode D4.

A8. The memory circuit of embodiment A7, wherein at least one of the third diode D3 and the fourth diode D4 is configured to be turned on by an optical signal provided by the input optical source.

A9. The memory circuit of embodiment A8, wherein the fifth ring resonator R5 is configured to write a bit value to a node electrically connected to the third ring resonator R3, the third diode D3, and the fifth ring resonator R5.

A10. The memory circuit of embodiment A8 or A9, wherein the sixth ring resonator R6 is configured to write an inverse bit value to a node electrically connected to the fourth ring resonator R4, the fourth diode D4, and the sixth ring resonator R6.

A11. The memory circuit of embodiment A9 or A10, wherein at least one of the fifth ring resonator R5 and the sixth ring resonator R6 write the bit value or inverse bit value, respectively, when supplied, by the first bit line B1 or the second bit line B2, respectively, with an optical signal substantially equal to a resonant frequency of the fifth ring resonator R5 and the sixth ring resonator R6, respectively.

A12. The memory circuit of embodiment A11, wherein the fifth ring resonator R5 and the sixth ring resonator R6 have substantially the same resonant frequency under substantially the same applied voltage and wherein the fifth ring resonator R5 and the sixth ring resonator R6 have substantially different resonant frequencies than the first ring resonator R1, the second ring resonator R2, the third ring resonator R3, and the fourth ring resonator R4.

A13. The memory circuit of any of the preceding embodiments, wherein the first ring resonator R1 is configured to select a first wavelength from the first waveguide W1 and transmit the first wavelength to the third waveguide, wherein the first wavelength corresponds to a resonant frequency of the first ring resonator R1.

A14. The memory circuit of embodiment A13, wherein the resonant frequency of the first ring resonator R1 is electrically adjusted by application of voltage to the first ring resonator R1 through the electrical coupling with the first diode D1.

A15. The memory circuit of any of the preceding embodiments, wherein the second ring resonator R2 is configured to select a second wavelength from the second waveguide W2 and transmit the second wavelength to the fourth waveguide, wherein the second wavelength corresponds to a resonant frequency of the second ring resonator R2.

A16. The memory circuit of embodiment A15, wherein the resonant frequency of the second ring resonator R2 is electrically adjusted by application of voltage to the second ring resonator R2 through the electrical coupling with the second diode D2.

A17. The memory circuit of any of the preceding embodiments, wherein the third ring resonator R3 is configured to select a third wavelength from the third waveguide W3 and transmit the third wavelength to the first bit line B1, wherein the third wavelength corresponds to a resonant frequency of the third ring resonator R3.

A18. The memory circuit of embodiment A17, wherein the third ring resonator R3 transmits the third wavelength to the first bit line B1 if and only if the third wavelength is substantially equal to the first wavelength.

A19. The memory circuit of embodiment A17, wherein the resonant frequency of the third ring resonator R3 is electrically adjusted by application of voltage to the third ring resonator R3 through the electrical coupling with the third diode D3 and a stored bit value.

A20. The memory circuit of embodiment A19, wherein the third wavelength is substantially equal to the first wavelength if any only if the voltage applied to the first ring resonator R1 through electrical coupling with the first diode D1 is substantially equal to the voltage applied to the third ring resonator R3 through electrical coupling with the third diode D3 and the stored bit value.

A21. The memory circuit of any of the preceding embodiments, wherein the fourth ring resonator R4 is configured to select a fourth wavelength from the second waveguide W2 and transmit the second wavelength to the second bit line B2, wherein the fourth wavelength corresponds to a resonant frequency of the fourth ring resonator R4.

A22. The memory circuit of embodiment A21, wherein the fourth ring resonator R4 transmits the fourth wavelength to the second bit line B2 if and only if the fourth wavelength is substantially equal to the second wavelength.

A23. The memory circuit of embodiment A21, wherein the resonant frequency of the fourth ring resonator R4 is electrically adjusted by application of voltage to the fourth ring resonator R4 through the electrical coupling with the fourth diode D4 and a stored inverse bit value.

A24. The memory circuit of embodiment A23, wherein the fourth wavelength is substantially equal to the second wavelength if any only if the voltage applied to the second ring resonator R2 through electrical coupling with the second diode D2 is substantially equal to the voltage applied to the fourth ring resonator R4 through electrical coupling with the fourth diode D4 and the stored inverse bit value.

A25. The memory circuit of any preceding embodiment, wherein first ring resonator R1, the second ring resonator R2, the third ring resonator R3, the fourth ring resonator R4 and have substantially the same resonant frequency under substantially the same applied voltage.

A26. The memory circuit of any one of embodiments A2 to A25, wherein the compute ring resonator RC is optically coupled to the first bit line B1.

A27. The memory circuit of embodiment A26, wherein the compute ring resonator RC has substantially the same dimensions as the first ring resonator R1 and the third ring resonator R3.

A28. The memory circuit of any one of embodiments A2 to A27, wherein the compute ring resonator RC comprises a set of parallel compute ring resonators, each of the set of parallel compute ring resonators optically coupled to the first bit line B1.

A29. The memory circuit of embodiment A28, wherein at least some of the set of parallel compute ring resonators have different resonant frequencies.

A30. The memory circuit of any one of embodiments A2 to A28, further comprising an inverse compute ring resonators IRC, the inverse compute ring resonator electrically coupled to at least one of the fourth ring resonator R4, the six ring resonator R6, and the fourth diode D4.

A31. The memory circuit of embodiment A30, wherein the inverse compute ring resonator IRC is optically coupled to the second bit line B2.

A32. The memory circuit of embodiment A30 or A31, wherein the inverse compute ring resonator IRC comprises a set of parallel inverse compute ring resonators, each of the set of parallel inverse compute ring resonators optically coupled to the second bit line B2.

A33. The memory circuit of embodiment A32, wherein at least some of the set of parallel inverse compute ring resonators have different resonant frequencies.

A34. The memory circuit of any preceding embodiment, wherein the second bit line B2 is an inverse of the first bit line B1.

A35. The memory circuit of any preceding embodiment, wherein at least one ring resonator of the first ring resonator R1, the second ring resonator R2, the third ring resonator R3, the fourth ring resonator R4, the fifth ring resonator R5 and the sixth ring resonator R6 is a micro ring resonator.

A36. The memory circuit of any preceding embodiment, wherein the first waveguide W1 and the second waveguide W2 cross at a waveguide crossing.

A37. A method of fabricating the memory circuit of any one of embodiments A1 to A37.

A38. An array of memory circuits, comprising multiple of the memory circuit any one of embodiments A1 to A37.

A39. A method of fabricating the array of embodiment A38.

A40. A method comprising operating any one of the memory circuits of embodiments A1 to A37.

A41. The method of embodiment A40, comprising writing a bit value to the memory circuit by supplying one or more write optical signals.

A42. The method of embodiment A41, wherein supplying the write one or more optical signals comprises supplying the optical signals to one or more of the set of electro-optical switches.

A43. The method of embodiment A40, comprising reading a bit value of the memory circuit by supplying one or more read optical signals and reading one or more output optical signals.

A44. The method of embodiment A43, wherein supplying the one or more read optical signals comprises supplying the optical signals to the compute element and wherein reading the one or more output optical signals comprises reading an output of a bit line.

A45. The method of embodiment A44, wherein reading the output of the bit line further comprises reading an output of an inverse bit line.

A46. The method of embodiment A40, wherein operating the memory circuit comprises steps for performing a multiplication operation.

A47. The method of embodiment A40, wherein operating the memory circuit comprises steps for performing a multiple multiplication operation.

A48. The method of embodiment A40, wherein operating the memory circuit comprises steps for performing a transpose operation.

A49. The method of embodiment A40, wherein operating the memory circuit comprises steps for performing a convolution operation.

A50. The method of embodiment A40, wherein operating the memory circuit comprises steps for performing an accumulation operation.

A51. The method of embodiment A40, wherein operating the memory circuit comprises steps for performing an addition operation.

A52. The method of embodiment A40, wherein operating the memory circuit comprises steps for in-memory computation.

A53. The memory circuit of any one of embodiments A1 to A36 or A38, further comprising tangible, non-transitory, machine readable medium storing instructions that when executed cause operations comprising the method of any one of embodiments A40 to A52.

1. A memory circuit comprising:
a first ring resonator R1 that optically couples a first waveguide W1 to a third waveguide W3, the first ring resonator R1 further electrically coupled to a first diode D1;
a second ring resonator R2 that optically couples a second waveguide W2 to a fourth waveguide W4, the second ring resonator R2 further electrically coupled to a second diode D2;
a third ring resonator R3 that optically couples the third waveguide W3 to a first bit line B1, the third ring resonator R3 further electrically coupled to a third diode D3;
a fourth ring resonator R4 that optically couples the fourth waveguide W4 to a second bit line B2, the fourth ring resonator R4 further electrically coupled to a fourth diode D4
a fifth ring resonator R5 that optically couples the second waveguide W2 to the first bit line B1, the fifth ring resonator R5 further electrically coupled to at least one of the third ring resonator R3 and the third diode D3; and
a sixth ring resonator R6 that optically couples the first waveguide W1 to the second bit line B2, the sixth ring resonator R6 further electrically coupled to at least one of the fourth ring resonator R4 and the fourth diode D4.

2. The memory circuit of claim 1, further comprising a compute ring resonator RC optically coupled to the first bit line, the compute ring resonator RC electrically coupled to at least one of the third ring resonator R3, the fifth ring resonator R5, and the third diode D3.

3. The memory circuit of claim 2, wherein at least one of the first diode D1, the second diode D2, the third diode D3, and the fourth diode D4 is a photodiode.

4. The memory circuit of claim 3, wherein the first waveguide is optically coupled to the second diode D2 and wherein the second waveguide is optically coupled to the first diode D1.

5. The memory circuit of claim 4, wherein the first diode D1, the second diode D2, the third diode D3, and the fourth diode D4 are electrically coupled.

6. The memory circuit of claim 5, wherein cathodes of the first diode D1, the second diode D2, the third diode D3, and the fourth diode D4 are electrically coupled to a bias voltage source.

7. The memory circuit of claim 6, wherein an input optical source is optically coupled to at least one of the third diode D3 and the fourth diode D4.

8. The memory circuit of claim 7, wherein at least one of the third diode D3 and the fourth diode D4 is configured to be turned on by an optical signal provided by the input optical source.

9. The memory circuit of claim 8, wherein the fifth ring resonator R5 is configured to write a bit value to a node electrically connected to the third ring resonator R3, the third diode D3, and the fifth ring resonator R5.

10. The memory circuit of claim 9, wherein the sixth ring resonator R6 is configured to write an inverse bit value to a node electrically connected to the fourth ring resonator R4, the fourth diode D4, and the sixth ring resonator R6.

11. The memory circuit of claim 10, wherein at least one of the fifth ring resonator R5 and the sixth ring resonator R6 write the bit value or inverse bit value, respectively, when supplied, by the first bit line B1 or the second bit line B2, respectively, with an optical signal substantially equal to a resonant frequency of the fifth ring resonator R5 and the sixth ring resonator R6, respectively.

12. The memory circuit of claim 11, wherein the fifth ring resonator R5 and the sixth ring resonator R6 have substantially the same resonant frequency under substantially the same applied voltage and wherein the fifth ring resonator R5 and the sixth ring resonator R6 have substantially different resonant frequencies than the first ring resonator R1, the second ring resonator R2, the third ring resonator R3, and the fourth ring resonator R4.

13. The memory circuit of claim 1, wherein the first ring resonator R1 is configured to select a first wavelength from the first waveguide W1 and transmit the first wavelength to the third waveguide, wherein the first wavelength corresponds to a resonant frequency of the first ring resonator R1.

14. The memory circuit of claim 13, wherein the resonant frequency of the first ring resonator R1 is electrically adjusted by application of voltage to the first ring resonator R1 through the electrical coupling with the first diode D1.

15. The memory circuit of claim 13, wherein the second ring resonator R2 is configured to select a second wavelength from the second waveguide W2 and transmit the second wavelength to the fourth waveguide, wherein the second wavelength corresponds to a resonant frequency of the second ring resonator R2.

16. The memory circuit of claim 15, wherein the resonant frequency of the second ring resonator R2 is electrically adjusted by application of voltage to the second ring resonator R2 through the electrical coupling with the second diode D2.

17. The memory circuit of claim 15, wherein the third ring resonator R3 is configured to select a third wavelength from the third waveguide W3 and transmit the third wavelength to the first bit line B1, wherein the third wavelength corresponds to a resonant frequency of the third ring resonator R3.

18. The memory circuit of claim 17, wherein the third ring resonator R3 transmits the third wavelength to the first bit line B1 if and only if the third wavelength is substantially equal to the first wavelength.

19. The memory circuit of claim 17, wherein the resonant frequency of the third ring resonator R3 is electrically adjusted by application of voltage to the third ring resonator R3 through the electrical coupling with the third diode D3 and a stored bit value.

20. The memory circuit of claim 19, wherein the third wavelength is substantially equal to the first wavelength if any only if the voltage applied to the first ring resonator R1 through electrical coupling with the first diode D1 is substantially equal to the voltage applied to the third ring resonator R3 through electrical coupling with the third diode D3 and the stored bit value.
